(19) United States
(12) Patent Application Publication
(10) Pub. No.: US 2015/0105032 A1
(43) Pub. Date: Apr. 16, 2015

(54) DYNAMIC BIAS TO IMPROVE SWITCH LINEARITY

(71) Applicant: QUALCOMM Incorporated, San Diego, CA (US)

(72) Inventors: Xinwei WANG, Dunstable, MA (US); James F. IMBORNONE, Methuen, MA (US); Xiangdong ZHANG, Westford, MA (US)

(73) Assignee: QUALCOMM Incorporated, San Diego, CA (US)

(21) Appl. No.: 14/054,634

(22) Filed: Oct. 15, 2013

(51) Int. Cl. H03K 17/16; H04B 1/40

(52) U.S. Cl. CPC H03K 17/161; H04B 1/40
USPC 455/77

(57) ABSTRACT

Exemplary embodiments are related to a dynamic gate bias for an electronic switch. A device may include a radio-frequency (RF) switch configured to receive an RF signal. The device may further include a bias generator configured to convey a bias signal based on a power level of the RF signal to the RF switch.

### BACKGROUND

1. Field

The present invention relates generally to improving the linearity of a switch in an “on” state. More specifically, embodiments of the present invention relate to providing a dynamic bias to a switch for improving “on” state linearity of the switch.

2. Background

Metal-Oxide Semiconductor Field Effect Transistor (MOSFET) technology can be found in many electronics including microprocessors, microcontrollers, static RAM, and other digital logic circuits. Due to high noise immunity and low static power consumption, MOSFET are often used in designs to switch between one of a plurality of signals. Popular switches using MOSFETs include complementary metal-oxide semiconductor (CMOS) switches.

CMOS switches are often used in antenna tuning circuits, which require high linearity (i.e., low distortion) to allow for coexistence of several operating frequencies while maintaining a low receiver noise/spur floor and also satisfying regulatory emission masks. CMOS switches may be implemented in a front-end application of a wireless transceiver (i.e., as radio-frequency (RF) switches) and may be used to route signals back and forth between an antenna and a power amplifier for transmitting a signal and the antenna and a low noise amplifier for receiving a signal. The linearity of an RF switch is a key contributor to the overall transmitter linearity. Conventional antenna switches optimize switch size with a fixed gate bias.

A need exists for improving the linearity of an electronic switch in an “on” state. More specifically, a need exists for embodiments related to applying a dynamic bias to an RF switch to improve the linearity of the RF switch in an “on” state.

### BRIEF DESCRIPTION OF THE DRAWINGS

FIG. 1 depicts a device, according to an exemplary embodiment of the present invention.

FIG. 2A illustrates a modulated radio-frequency signal.

FIG. 2B illustrates a detected parameter of the radio-frequency signal of FIG. 2A.

FIG. 2C is a plot including the detected parameter of the radio-frequency signal of FIG. 2A and a constant supply voltage.

FIG. 3 illustrates another device, in accordance with an exemplary embodiment of the present invention.

FIG. 4 illustrates another device, according to an exemplary embodiment of the present invention.

FIG. 5A illustrates a modulated radio-frequency signal.

FIG. 5B is a plot including a bias voltage varied based on RF power level conveyed to a switch relative to a constant supply voltage.

FIG. 6 is a flowchart depicting a method, in accordance with an exemplary embodiment of the present invention.

FIG. 7 is a flowchart depicting another method, in accordance with an exemplary embodiment of the present invention.

FIG. 8 illustrates a device including a switch coupled between an antenna and a transceiver.

FIG. 9 illustrates a wireless device, in accordance with an exemplary embodiment of the present invention.

### DETAILED DESCRIPTION

The detailed description set forth below in connection with the appended drawings is intended as a description of exemplary embodiments of the present invention and is not intended to represent the only embodiments in which the present invention can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the invention. It will be apparent to those skilled in the art that the exemplary embodiments of the invention may be practiced without these specific details. In some instances, well-known structures and devices are shown in block diagram form in order to avoid obscuring the novelty of the exemplary embodiments presented herein.

As will be appreciated by a person having ordinary skill in the art, an antenna tuner (e.g., an impedance matching circuit) and/or an antenna switch module of a wireless device may include radio-frequency (RF) matrix switches, which may require high linearity (i.e. low distortion) to allow for co-existence of several operating frequencies while maintaining a low receiver noise/spur floor and meeting regulatory emission masks. Further, as will be appreciated by a person having ordinary skill in the art, it may be desirable for a switch (e.g., a transistor) within a RF transceiver to operate in a linear region while in a conductive “on” state. However, as an amplitude of an RF signal received at a switch varies (e.g., increases), the linearity of the switch may suffer. In addition, constantly applying a relatively high bias voltage to a switch may undesirably stress and shorten the lifespan of the switch.

Exemplary embodiments, as described herein, are directed to devices and methods related to improving the linearity of a switch in an “on” state. According to one exemplary embodiment, a device may include a radio-frequency (RF) switch configured to receive an RF signal. The device may further include a bias generator configured to convey a bias signal based on a power level of the RF signal to the RF switch. According to another exemplary embodiment, a device may include a switch coupled to an antenna and configured to receive a radio-frequency (RF) signal. The device may also include a bias generator configured to receive a supply voltage and convey a bias voltage to the RF switch based on a power level of the RF signal to operate the switch in a conductive state.

According to another exemplary embodiment, the present invention includes methods for improving the linearity of an “on” state switch. Various embodiments of such a method may include conveying a radio-frequency (RF) signal to an RF switch. The method may further include generating a bias signal based on at least one of the RF signal and a supply voltage and biasing the RF switch with the bias signal. In accordance with another embodiment, a method may include receiving a radio-frequency (RF) signal at a switch. In addition, the method may include receiving a bias voltage at the switch that varies based on at least one of an envelope of the RF signal and an average power level of the RF signal.

Other aspects, as well as features and advantages of various aspects, of the present invention will become apparent to those of skill in the art through consideration of the ensuing description, the accompanying drawings and the appended claims.

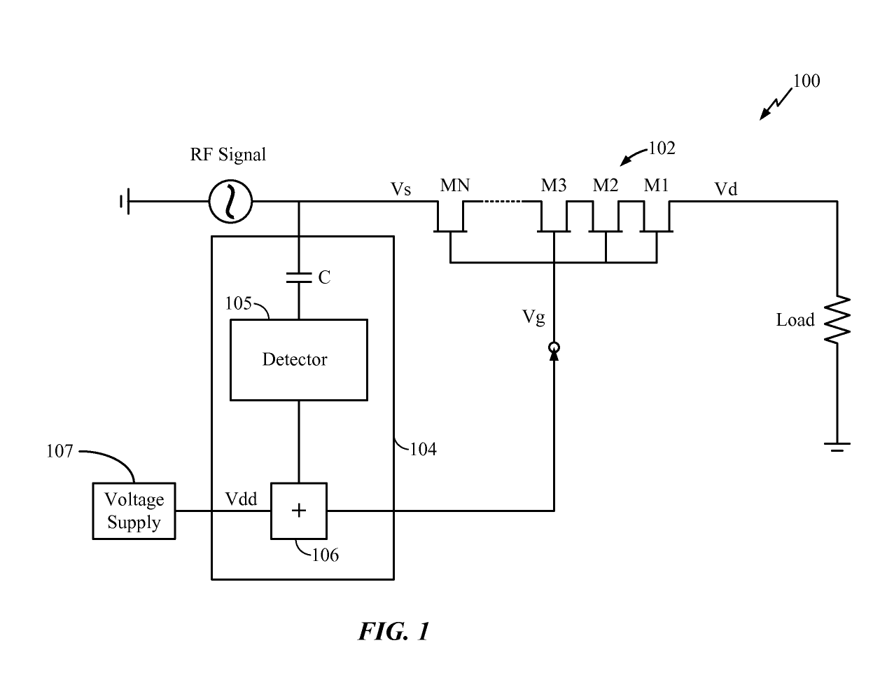

FIG. 1 illustrates a device 100, according to an exemplary embodiment of the present invention. Device 100 may also be referred to herein as a “closed-loop control device.” Device 100 includes an RF switch 102 configured to receive an RF signal. As a non-limiting example, the RF signal may comprise a transmit signal and may be conveyed from a power amplifier (not shown in FIG. 1). As another example, the RF signal may comprise a receive signal and may be received from an antenna. By way of example, RF switch 102 may comprise a plurality of transistors M1-MN in a series configuration with resistors/capacitors biasing network, wherein a transistor at one end of RF switch 102 (i.e., transistor MD has a drain coupled to a load (i.e., drain voltage Vd) and a source coupled to a drain of another transistor (i.e., transistor M2). Further, a source of a transistor at another end of RF switch 102 (i.e., transistor MN) may be configured to receive the RF signal (i.e., as a source voltage Vs). Further, each transistor of the plurality of transistors may have a gate configured to receive a gate voltage Vg. By way of example only, each of transistors M1-MN may comprise a CMOS n-type field effect transistor (NFET).

Device 100 may further include a bias generator unit 104 configured to receive the RF signal and a supply voltage from a voltage supply 107. Bias generator 104 may also be configured to generate a bias signal and convey a bias signal to RF switch 102. According to one exemplary embodiment as illustrated in FIG. 1, bias generator 104 may include a capacitor C, detector 105, and a combination network 106. By way of example, detector 105 may comprise an envelope detector, a power detector, or a combination thereof. Detector 105 may be configured to receive the RF signal and generate an envelope or average power DC signal in response thereto. According to another exemplary embodiment, envelope detector 105 may include a rectifier for receiving an RF signal and generating an envelope of the RF signal, which is conveyed to combination network 106. Further, according to one exemplary embodiment, detector 105 may include power detection circuitry to generate a DC signal equivalent to the average or root-mean-square (rms) power of the RF signal, which is conveyed to combination network 106.

Combination network 106 may be configured to receive a constant supply voltage Vdd (e.g., 2.7 volts) from voltage supply 107 and an envelope signal or an average power signal from detector 105. Further, combination network 106, which may also be referred to as a “summing network” or a “summing node” may be configured to combine (i.e., sum) supply voltage Vdd and the envelope signal, and convey a bias voltage for biasing RF switch 102. More specifically, combination network 106 may be configured to convey a bias voltage to a gate of each transistor in RF switch 102 to cause RF switch 102 to operate in a conductive “on” state.

It is noted that detector 105 may be configured to convey the envelope or average level of the RF signal to combination network 106 if an amplitude (i.e., the power level) of a received RF signal is equal to or greater than a threshold level (e.g., 15 dBm). Accordingly, if the amplitude of the RF signal is equal to or greater than a threshold level, the bias voltage conveyed to RF switch 102 will be greater than supply voltage Vdd. Stated another way, if the amplitude of the RF signal received at detector 105 is equal to or greater than a threshold level, the bias voltage conveyed to RF switch 102 will be increased proportional to the power level of the RF signal. Further, if the amplitude of the RF signal received at detector 105 is less than the threshold level, the bias voltage conveyed to RF switch 102 will be substantially equal to supply voltage Vdd.

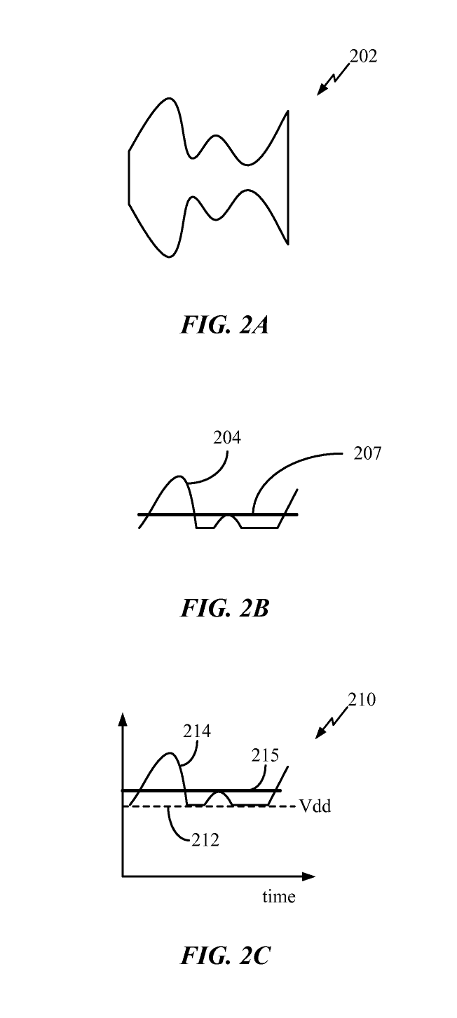

FIG. 2A depicts a modulated RF signal 202, such as the RF signal conveyed to RF switch 104 and signal generator 105. Further, FIG. 2B illustrates an envelope 204 and an average level 207 of the RF signal of FIG. 2A. By way of example, signal generator 105 (see FIG. 1) may be configured to convey the envelope or average level illustrated in FIG. 2B to combination network 106 (see FIG. 1). FIG. 2C is a plot 210 including a signal 212 representing supply voltage Vdd, a signal 214 representing the envelope, and a signal 215 representing the average level of the RF signal conveyed to RF switch 102 (see FIG. 1).

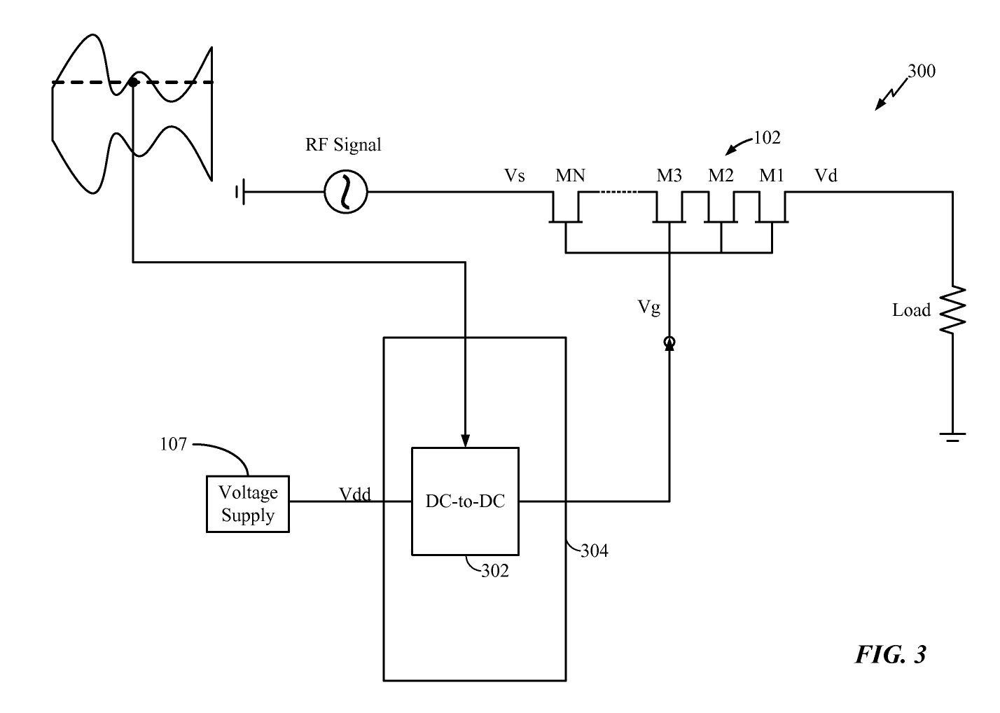

FIG. 3 depicts a device 300, in accordance with an exemplary embodiment of the present invention. Device 300 may also be referred to herein as an “open-loop control device.” Device 300 includes RF switch 102, which, as noted above, may comprise a plurality of transistors M1-MN in a series configuration with resistors/capacitors biasing network. According to one exemplary embodiment, transistor M1 of RF switch 104 has a drain coupled to load and a source coupled to a drain of another transistor (i.e., transistor M2). Further, a source of transistor MN may be configured to receive the RF signal.

Device 300 further includes a bias generator 304, which, in this exemplary embodiment, may comprise a DC-to-DC converter 302. DC-to-DC converter 302 may be configured to receive constant supply voltage Vdd and a control signal, and convey a bias voltage to RF switch 102. More specifically, DC-to-DC converter 302 may be configured to receive a control signal, which depending on an average power value of an RF signal received at RF switch 102, may cause DC-to-DC converter 302 to raise, lower, or maintain a level of a bias voltage supplied to RF switch 102. As will be appreciated by a person having ordinary skill in the art, converter 302 may function as a charge pump to modify a voltage level of the bias voltage supplied to RF switch 102.

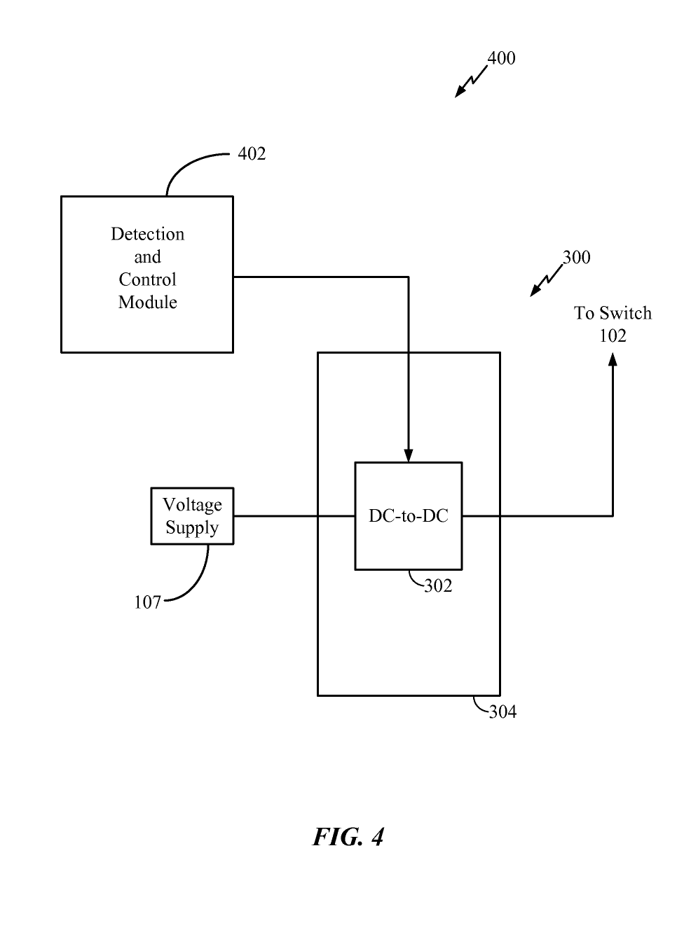

FIG. 4 illustrates a device 400, according to an exemplary embodiment of the present invention. Device 400 includes device 300, as described above with reference to FIG. 3, and a detection and control module 402. According to one exemplary embodiment, detection and control module 402 may be configured to generate and convey a control signal to DC-to-DC converter 302 for controlling a voltage level of the bias voltage generated by DC-to-DC converter 302 and conveyed to RF switch 102. More specifically, detection and control module 402 may be configured to determine an average power value of the RF signal conveyed to RF switch 102 and, depending on the average power value, may generate and convey the control signal to DC-to-DC converter 302. It is noted that, according to one exemplary embodiment, detection and control module 402 may be configured to determine the average power value of the RF signal received at RF switch 102. As one non-limiting example, detection and control module 402 may include a root mean square (RMS) detector for determining an average power value of the RF signal. According to another exemplary embodiment, detection and control 402 may receive a signal (e.g., from a remote power detector) indicative of the average power level of the RF signal being received at RF switch 102.

By way of example only, if the amplitude (e.g., the power level) of the RF signal received at RF switch 102 is substantially equal to 20 dBm, DC-to-DC converter 302 may convey a bias voltage of substantially 3.5 volts to RF switch 102. As another example, if the power level of the RF signal received at RF switch 102 is substantially equal to 15 dBm, DC-to-DC converter 302 may convey a bias voltage of substantially 3.0 volts to RF switch 102. As yet another example, if the power level of the RF signal received at RF switch 102 is substantially equal to 10 dBm, DC-to-DC converter 302 may convey a bias voltage of substantially 2.7 volts to RF switch 102.

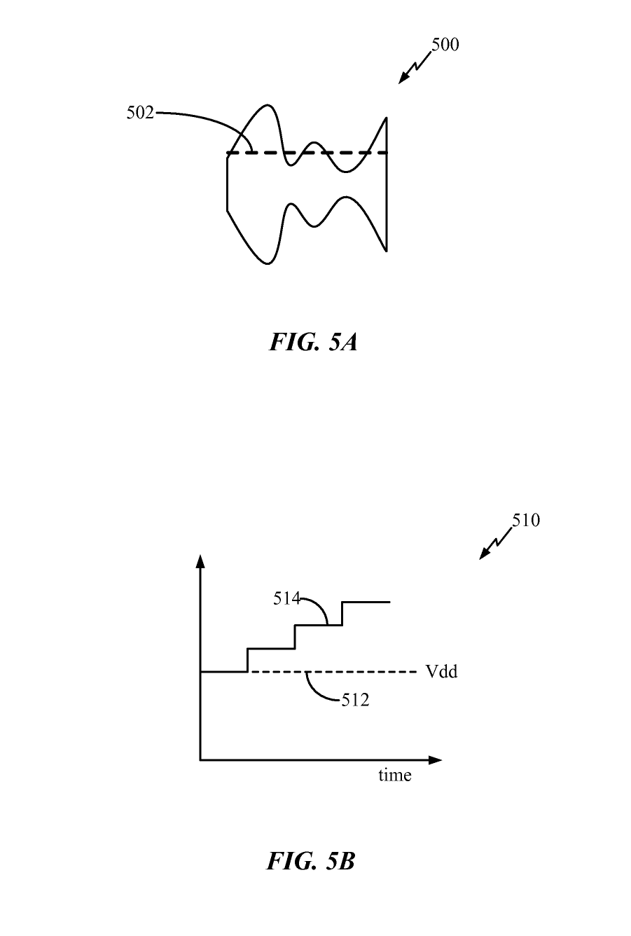

FIG. 5A illustrates an RF signal 500, such as an RF signal received at RF switch 102 (see FIG. 3). A reference numeral 502, as depicted in FIG. 5A, represents an average power level of RF signal 500. Further, FIG. 5B is a plot 500 including a signal 512 representing constant supply voltage Vdd and a signal 514 representing a level of an example bias voltage conveyed from DC to DC converter 302 to RF switch 102. As illustrated in FIG. 5A, signal 514 is increasing over time in response to an increase in an average power level of an RF signal received at RF switch 102.

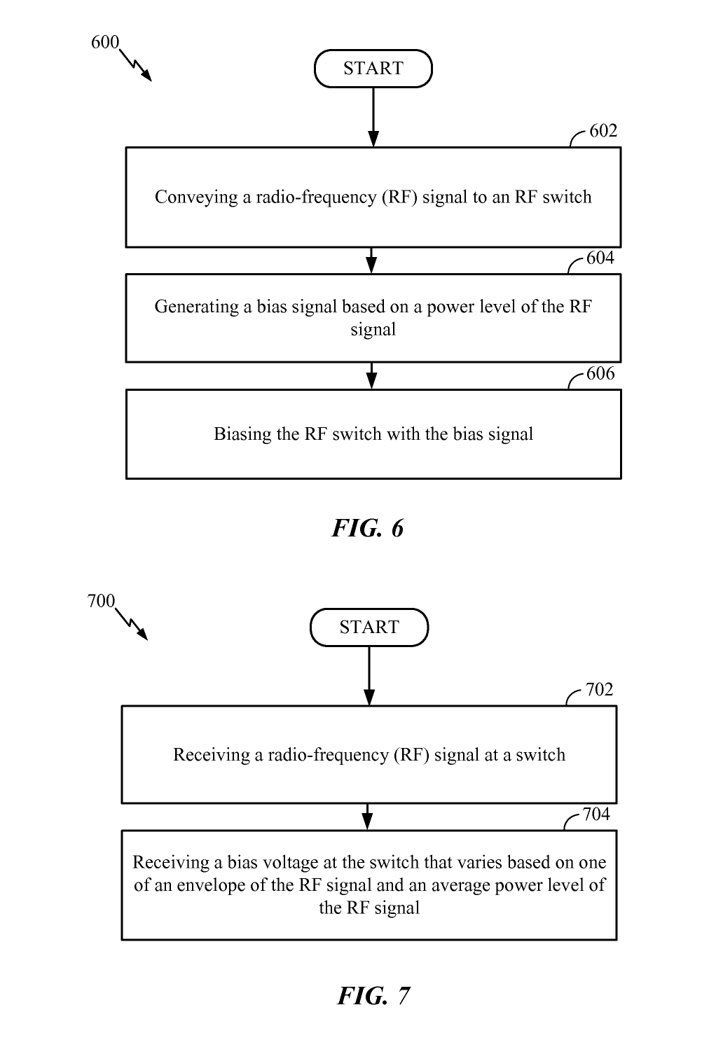

FIG. 6 is a flowchart illustrating a method 600, in accordance with one or more exemplary embodiments. Method 600 may include conveying a radio-frequency (RF) signal to an RF switch (depicted by numeral 602). Method 600 may also include generating a bias signal based on a power level of the RF signal (depicted by numeral 604). Moreover, method 600 may include biasing the RF switch with the bias signal (depicted by numeral 606).

FIG. 7 is a flowchart illustrating another method 700, in accordance with one or more exemplary embodiments. Method 700 may include receiving a radio-frequency (RF) signal at a switch (depicted by numeral 702). Method 700 may further include receiving a bias voltage at the switch that varies based on one of an envelope of the RF signal and/or an average power level of the RF signal (depicted by numeral 704).

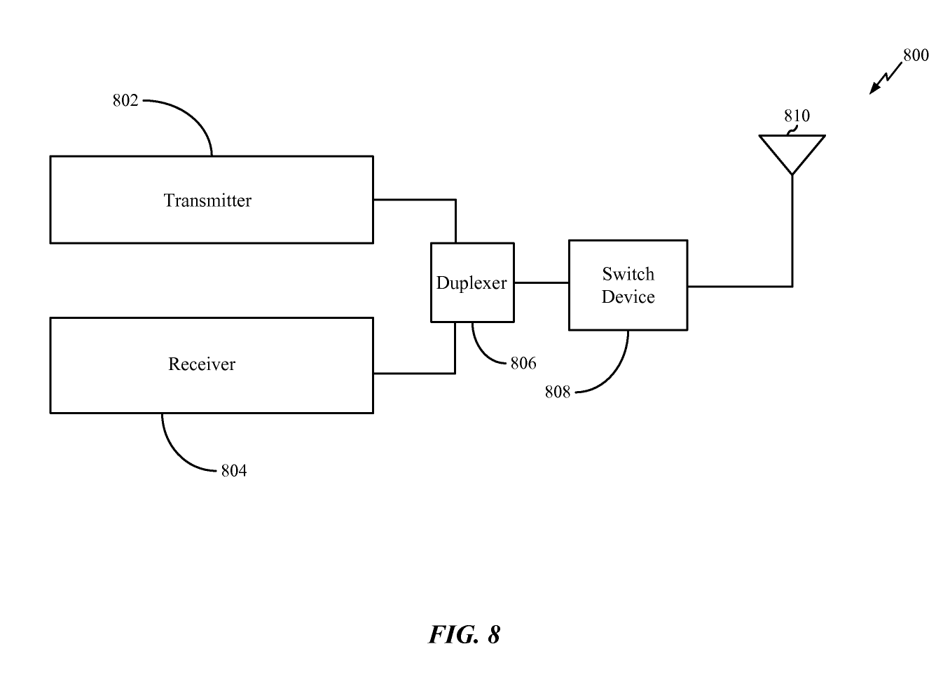

FIG. 8 illustrates a device 800, in accordance to an exemplary embodiment of the present invention. Device 800, which may comprise an RF front-end, includes a transmitter 802, a receiver 804, a duplexer 806, and an antenna 810. Further, device 800 includes a switch device 808, which may comprise device 100 illustrated FIG. 1, device 300 illustrated in FIG. 3, device 400 illustrated in FIG. 4, or any suitable combination thereof.

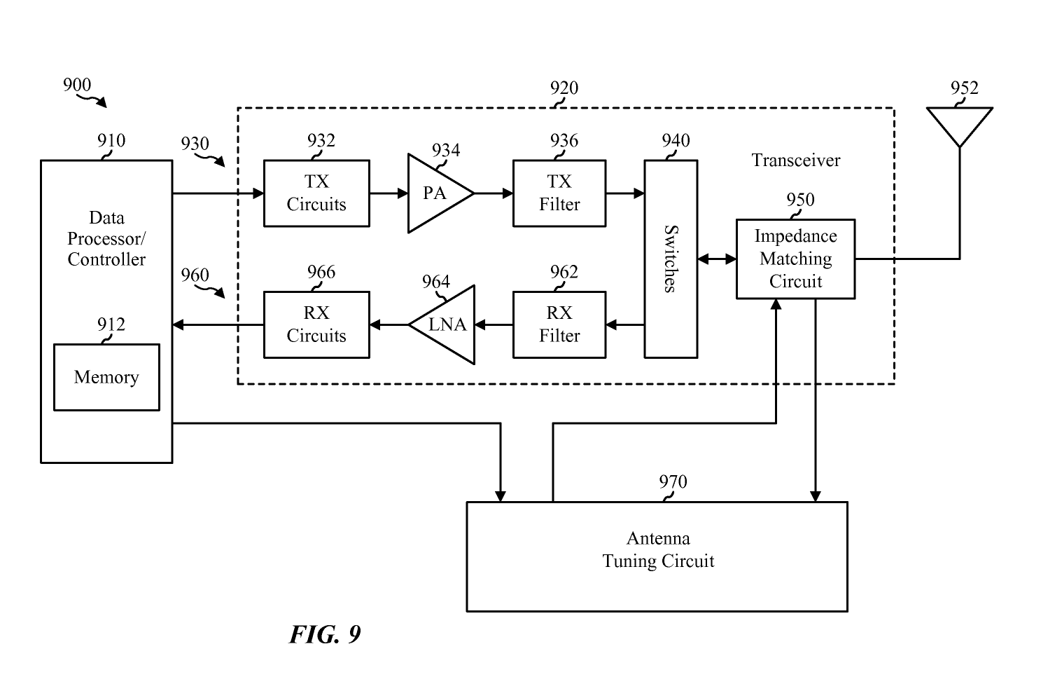

FIG. 9 shows a block diagram of an exemplary design of a wireless device 900. In this exemplary design, wireless device 900 includes a data processor/controller 910, a transceiver 920, an adaptive tuning circuit 970, and an antenna 952. Transceiver 920 includes a transmitter 930 and a receiver 960 that support bi-directional wireless communication. Wireless device 900 may support Long Term Evolution (LTE), Code Division Multiple Access (CDMA) 1X or cdma2000, Wideband CDMA (WCDMA), Global System for Mobile Communications (GSM), IEEE 802.11, etc.

In the transmit path, data processor 910 processes (e.g., encodes and modulates) data to be transmitted and provides an analog output signal to transmitter 930. Within transmitter 930, transmit circuits 932 amplify, filter, and up-convert the analog output signal from baseband to RF and provide a modulated signal. Transmit circuits 932 may include amplifiers, filters, mixers, an oscillator, a local oscillator (LO) generator, a phase locked loop (PLL), etc. A power amplifier (PA) 934 receives and amplifies the modulated signal and provides an amplified RF signal having the proper output power level. Transmit filter 936 filters the amplified RF signal to pass signal components in a transmit band and attenuates signal components in a receive band. Transmit filter 936 provides an output RF signal, which is routed through switches 940 and an impedance matching circuit 950 and transmitted via antenna 952. Impedance matching circuit 950 performs impedance matching for antenna 952 and is also referred to as an antenna tuning circuit, a tunable matching circuit, etc.

In the receive path, antenna 952 receives signals from base stations and/or other transmitter stations and provides a received RF signal, which is routed through impedance matching circuit 950 and switches 940 and provided to receiver 960. Within receiver 960, a receive filter 962 filters the received RF signal to pass signal components in the receive band and attenuate signal components in the transmit band. An LNA 964 amplifies a filtered RF signal from receive filter 962 and provides an input RF signal. Receive circuits 966 amplify, filter, and down-convert the input RF signal from RF to baseband and provide an analog input signal to data processor 910. Receive circuits 966 may include amplifiers, filters, mixers, an oscillator, an LO generator, a PLL, etc.

Adaptive tuning circuit 970 tunes or adjusts impedance matching circuit 950 such that good performance can be achieved for data transmission and reception. Impedance matching circuit 950 may include a digital variable capacitor (DVC) (not shown in FIG. 9) having a capacitance that can be varied in discrete units with a digital control signal. In addition, according to an exemplary embodiment of the present invention, impedance matching circuit 950 may include one or more of device 100, as described above with reference to FIG. 1, one or more of device 300, as described above with reference to FIG. 3, one or more of device 400, as described above with reference to FIG. 4, or a combination thereof.

All or a portion of transceiver 920 and adaptive tuning circuit 970 may be implemented on one or more analog integrated circuits (ICs), RF ICs (RFICs), mixed-signal ICs, etc. Power amplifier 934 and possibly other circuits may be implemented on a separate IC or module. Impedance matching circuit 950 and possibly other circuits may also be implemented on a separate IC or module.

Data processor/controller 910 may perform various functions for wireless device 900. For example, data processor 910 may perform processing for data being transmitted via transmitter 930 and received via receiver 960. Controller 910 may control the operation of TX circuits 932, RX circuits 966, switches 940, and/or adaptive tuning circuit 970. Memory 912 may store program codes and data for data processor/controller 910. Memory 912 may be internal to data processor/controller 910 (as shown in FIG. 9) or external to data processor/controller 910 (not shown in FIG. 9). Data processor/controller 910 may be implemented on one or more application specific integrated circuits (ASICs) and/or other ICs.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the exemplary embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

The various illustrative logical blocks, modules, and circuits described in connection with the exemplary embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosed exemplary embodiments is provided to enable any person skilled in the art to make or use the present invention. Various modifications to these exemplary embodiments will be readily apparent to those skilled in the art, and the generic principles defined herein may be applied to other embodiments without departing from the spirit or scope of the invention. Thus, the present invention is not intended to be limited to the exemplary embodiments shown herein but is to be accorded the widest scope consistent with the principles and novel features disclosed herein.

What is claimed is:

1. A device, comprising:
a radio-frequency (RF) switch configured to receive an RF signal; and
a bias generator configured to convey a bias signal based on a power level of the RF signal to the RF switch.

2. The device of claim 1, the RF switch comprising a plurality of transistors in a series configuration.

3. The device of claim 1, the bias generator comprising one of an envelope detector and a power detector configured to receive the RF signal and generate one of an envelope and an average power level of the RF signal.

4. The device of claim 3, the one of the envelope detector and the power detector configured to generate one of the envelope and the average power level if a power level of the RF signal is above a threshold level.

5. The device of claim 1, the bias generator comprising a rectifier configured to receive the RF signal and generate an envelope of the RF signal.

6. The device of claim 1, the bias generator comprising a DC-to-DC converter configured to receive a control signal for adjusting a voltage level of the bias signal.

7. The device of claim 1, further comprising a voltage supply configured to convey a supply voltage to the bias generator.

8. The device of claim 1, wherein the bias generator is configured to convey the bias signal having a voltage level proportional to a power level of the RF signal.

9. The device of claim 1, wherein the bias generator comprises:
a signal generator for generating one of an envelope and an average power level of the RF signal; and
a summing node for receiving the envelope and a supply voltage and summing one of the envelope and the average power level and the supply voltage to generate the bias signal.

10. The device of claim 1, wherein the bias generator comprises a signal generator configured for:
receiving a supply voltage and a control signal; and
generating the bias signal based on the supply voltage and the control signal.

11. A device, comprising:
a switch coupled to an antenna an configured to receive a radio-frequency (RF) signal; and
a bias generator configured to receive a supply voltage and convey a bias voltage to the RF switch based on an amplitude of the RF signal to operate the switch in a conductive state.

12. The device of claim 11, further comprising a controller configured to determine the amplitude of the RF signal and convey a signal to the bias generator for controlling a voltage level of the bias voltage.

13. The device of claim 11, the bias generator configured to:
convey the bias voltage comprising a sum of the supply voltage and an envelope of the RF signal if the amplitude of the RF signal is substantially equal to or greater than a threshold level; and
convey the bias voltage comprising the supply voltage if the amplitude of the RF signal is substantially less than the threshold level.

14. A method, comprising:
conveying a radio-frequency (RF) signal to an RF switch;
generating a bias signal based on a power level of the RF signal; and
biasing the RF switch with the bias signal.

15. The method of claim 14, wherein conveying a RF signal comprises conveying the RF signal to the RF switch including a plurality of transistors in a series configuration.

16. The method of claim 14, wherein generating a bias signal comprises generating the bias signal with one of an envelope detector and a power detector.

17. The method of claim 14, wherein generating a bias signal comprises detecting one of an envelope and an average power level of the RF signal.

18. The method of claim 14, wherein generating a bias signal comprises generating the bias signal based on each of the RF signal and the supply voltage if a power level of the RF signal is substantially equal to or greater than a threshold value.

19. The method of claim 14, wherein generating a bias signal comprises generating the bias signal based the supply voltage if a power level of the RF signal is substantially less than a threshold value.

20. A method, comprising:
receiving a radio-frequency (RF) signal at a switch; and
receiving a bias voltage at the switch that varies based on one of an envelope of the RF signal and an average power level of the RF signal.

21. The method of claim 20, wherein receiving a bias voltage comprises receiving the bias voltage that varies based on the envelope of the RF signal, wherein the bias voltage is further based on a supply voltage.

22. The method of claim 20, wherein receiving a bias voltage comprises receiving a bias voltage substantially equal to a supply voltage if the power level of the RF signal is below a threshold value.

23. A device, comprising:
means for conveying a radio-frequency (RF) signal to an RF switch;
means for generating a bias signal based on a power level of the RF signal; and
means for biasing the RF switch with the bias signal.

24. The device of claim 23, the means for generating a bias signal comprising means for generating a signal comprising the envelope of the RF signal.

25. The device of claim 23, further comprising means for summing an envelope of the RF signal and the supply voltage to generate the bias signal.
